(19) United States
(12) Patent Application Publication
(10) Pub. No.: US 2015/0002787 A1
(43) Pub. Date: Jan. 1, 2015

(54) PHOTOVOLTAIC MOBILE DEVICE

(71) Applicant: HannStar Display Corporation, New Taipei City (TW)

(72) Inventors: Chia-Shin WENG, Chiayi City (TW); Wei-Ren LO, Taipei City (TW); Chao-Jung CHEN, Changhua County (TW); Chien-Liang KUO, Taipei City (TW); Chih-Pin LIN, Tainan City (TW)

(73) Assignee: HannStar Display Corporation, New Taipei City (TW)

(21) Appl. No.: 14/173,792

(22) Filed: Feb. 5, 2014

(30) Foreign Application Priority Data
Jun. 28, 2013 (CN) 201310268133.2

(51) Int. Cl. G06F 1/32; H01L 27/32; F21V 8/00

(52) U.S. Cl. CPC G06F 1/3265; G02B 6/0001; H01L 27/3227
USPC 349/65; 257/40

(57) ABSTRACT

A photovoltaic mobile device includes a backlight module and a liquid crystal display panel. The backlight module includes a plurality of light sources, a photovoltaic substrate, and a light guide plate. The light sources are disposed at a side of the light guide plate, and the light guide plate is disposed above the photovoltaic substrate. The liquid crystal display panel is disposed on the light guide plate. The photovoltaic substrate includes a plurality of strip type photovoltaic components.

### RELATED APPLICATIONS

This application claims priority to Chinese Application Serial Number 201310268133.2, filed Jun. 28, 2013, which is herein incorporated by reference.

### BACKGROUND

1. Field of Invention

The present invention relates to a mobile device.

2. Description of Related Art

With the rapid development of the computer-communication-consumer (3C) industry, mobile devices are more frequently used as tools to assist our daily life. Popular mobile devices include personal digital assistants (PDAs), mobile phones, smart phones, notebook computers, etc. To increase the interest of consumers of mobile devices, a wide variety of functions have been developed.

However, the requirements associated with processors have increased along with the development of the functions of mobile devices, resulting in greater power consumption. Therefore, there is a need for extending the standby time and reducing the charging frequency of mobile devices.

### SUMMARY

The present disclosure provides a photovoltaic mobile device, in which a plurality of strip type photovoltaic components are arranged behind a display surface in order to extend the standby time and reduce the charging frequency of the mobile device.

An aspect of the invention provides a photovoltaic mobile device. The photovoltaic mobile device includes a backlight module and a liquid crystal display panel. The backlight module includes a plurality of light sources, a photovoltaic substrate, and a light guide plate. The light sources are disposed at a side of the light guide plate, and the light guide plate is disposed above the photovoltaic substrate. The liquid crystal display panel is disposed on the light guide plate. The photovoltaic substrate includes a plurality of strip type photovoltaic components.

In one or more embodiments, the photovoltaic mobile device further includes a light source bracket and a photovoltaic layer. The light sources are disposed in the light source bracket, and the photovoltaic layer is coated on a surface of the light source bracket facing the light sources.

In one or more embodiments, the liquid crystal display panel is a normally white liquid crystal display panel.

In one or more embodiments, the photovoltaic mobile device further includes a touch panel disposed on the liquid crystal display panel.

In one or more embodiments, the photovoltaic mobile device further includes a 3D-barrier disposed on the liquid crystal display panel.

In one or more embodiments, the light guide plate includes a plurality of strip cavities disposed on a surface of the light guide plate facing the photovoltaic substrate, in which the strip cavities are disposed corresponding to the strip type photovoltaic components respectively, and a cross-sectional profile of the strip cavities is a curved shape.

In one or more embodiments, the photovoltaic mobile device further includes an optical component. The optical component includes a micro lens array surface facing the liquid crystal display panel, and an alternative light passage surface facing the photovoltaic substrate.

In one or more embodiments, the alternative light passage surface includes a plurality of first one-way light passages and a plurality of second one-way light passages, and the first one-way light passage and the second one-way light passage are alternatingly arranged.

In one or more embodiments, the photovoltaic substrate further includes a plurality of reflection strips, and the strip type photovoltaic components and the reflection strips are alternatingly arranged.

Another aspect of the invention provides a photovoltaic mobile device. The photovoltaic mobile includes a photovoltaic substrate and an organic light emitting diode display panel. The photovoltaic substrate includes a plurality of strip type photovoltaic components. The organic light emitting diode display panel is disposed on the photovoltaic substrate.

In one or more embodiments, the photovoltaic mobile device further includes a touch panel disposed on the organic light emitting diode display panel.

In one or more embodiments, the photovoltaic mobile device further includes a 3D-barrier disposed on the organic light emitting diode display panel.

In one or more embodiments, the photovoltaic mobile device further includes an optical component. The optical component includes a micro lens array surface facing the organic light emitting diode display panel, and an alternative light passage surface facing the photovoltaic substrate.

In one or more embodiments, the alternative light passage surface includes a plurality of first one-way light passages and a plurality of second one-way light passages, and the first one-way light passage and the second one-way light passage are alternatingly arranged.

In one or more embodiments, the photovoltaic substrate further includes a plurality of reflection strips, and the strip type photovoltaic components and the reflection strips are alternatingly arranged.

The photovoltaic mobile device uses the strip type photovoltaic components which are disposed behind the display surface to collect light provided by a backlight module and convert the light into electric energy which can be utilized by the mobile device. As a result, the standby time of the mobile device can be increased and the charge frequency can be reduced.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a cross-sectional schematic view of a first embodiment of a photovoltaic mobile device of the invention;

FIG. 2 is a top view of an embodiment of a photovoltaic substrate illustrated in FIG. 1; and

FIG. 3-FIG. 11 are cross-sectional schematic views of different embodiments of the photovoltaic mobile device of the invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

The present disclosure provides a mobile device having a photovoltaic function. A photovoltaic component is assembled in the mobile device for converting light energy provided by a backlight module into electric energy which can be utilized by the mobile device. As a result, the standby time of the mobile device can be increased.

FIG. 1 is a cross-sectional schematic view of a first embodiment of a photovoltaic mobile device of the invention. The photovoltaic mobile device 100 includes a backlight module 150 and a liquid crystal display panel 140. The liquid crystal display panel 140 is disposed above the backlight module 150. The backlight module 150 includes a plurality of light sources 152, a photovoltaic substrate 154 including a plurality of strip type photovoltaic components 1540 and a plurality of reflection strips 1542, and a light guide plate 156. The light sources 152 are disposed at opposite sides of the light guide plate 156. The light sources 152 are disposed in a light source bracket 158 The photovoltaic substrate 154 is disposed between the light source bracket 158 and the light guide plate 156. The photovoltaic mobile device further includes a photovoltaic layer 1580. The photovoltaic layer 1580 is coated on an inner surface of the light source bracket 158 facing the light sources 152.

The backlight module 150 is always active even when the photovoltaic mobile device 100 is not operated. The photovoltaic mobile device 100 includes the strip type photovoltaic components 1540 to convert a part of the light provided by the light sources 152 into electric energy, and the electric energy can be utilized by the photovoltaic mobile device 100. Therefore, the standby time of the photovoltaic mobile device 100 can be increased. Another part of the light provided by the light sources 152 is reflected by the reflection strips 1542 exposed between the strip type photovoltaic components 1540 toward the liquid crystal display panel 140. Hence, the backlight module 150 still provides the function of illuminating the liquid crystal display panel 140.

The strip type photovoltaic components 1540 are disposed between the light guide plate 156 and the photovoltaic substrate 154. The strip type photovoltaic components 1540 are arranged at the backside of the liquid crystal display panel 140. Therefore, the display function of the liquid crystal display panel 140 is not affected by the strip type photovoltaic components 1540. Furthermore, the strip type photovoltaic components 1540 have a very fine width of, for example, 150 μm or less, so that no mura is caused by the strip type photovoltaic components 1540.

The light sources 152 can be light emitting diodes or fluorescent lamps. When the light sources 152 are fluorescent lamps, the light provided by the light sources 152 is emitted outwardly in a uniform manner. Therefore, a significant portion of the light is not emitted onto the light guide plate 156 and is wasted. In this embodiment, the photovoltaic layer 1580 is disposed on the inner surface of the light source bracket 158. The photovoltaic layer 1580 faces the light sources 152 in order to receive the part of the light which is not directly emitted into the light guide plate 156. This part of the light received by the photovoltaic layer 1580 is further converted into electric energy and is utilized by the photovoltaic mobile device 100.

When the light sources 152 are light emitting diodes, due to the high degree of directivity of light emitting diodes, most of the light provided by the light emitting diodes directly enters the light guide plate 156. In this case, the photovoltaic layer 1580 disposed on the inner surface of the light source bracket 158 is utilized to receive the light provided from the light sources 152 on the opposite side of the backlight module 150, and the received light is converted into electric energy and is utilized by the photovoltaic mobile device 100.

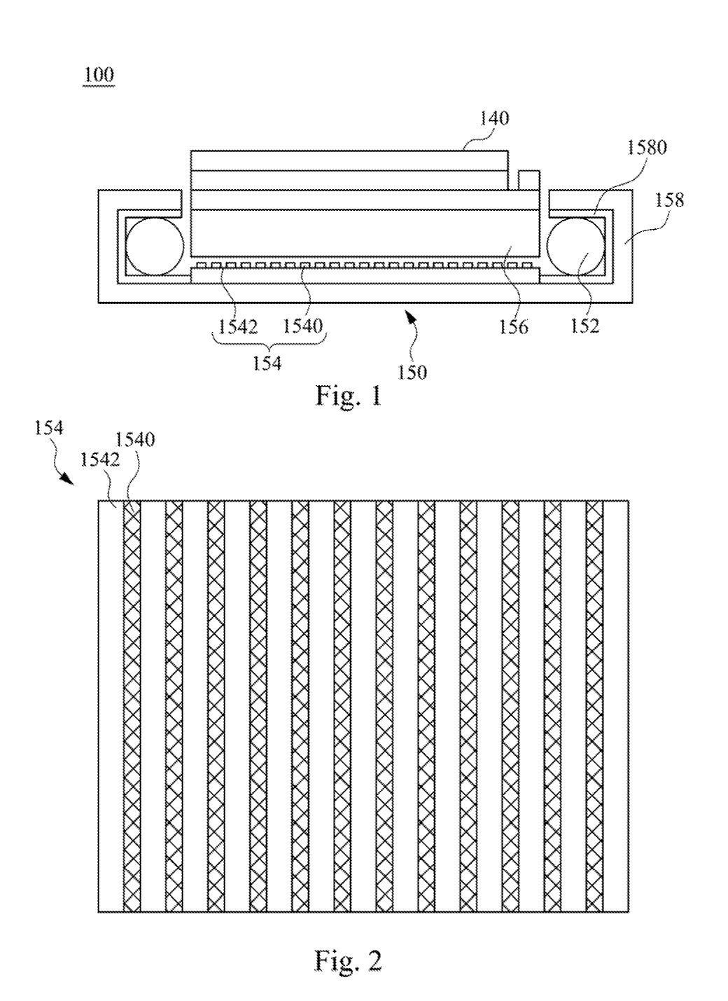

FIG. 2 is a top view of an embodiment of the photovoltaic substrate 154 as illustrated in FIG. 1. in this embodiment, the strip type photovoltaic components 1540 can be directly formed on a reflector to obtain the photovoltaic substrate 154 having the strip type photovoltaic components 1540 and a plurality of the reflection strips 1542 alternatingly arranged. In some embodiments, the photovoltaic substrate 154 having the strip type photovoltaic components 1540 and the reflection strips 1542 can be a photovoltaic material substrate partially coated with paste having light-reflecting material included therein. In this case also, the photovoltaic substrate 154 includes the strip type photovoltaic components 1540 and the reflection strips 1542 alternatingly arranged.

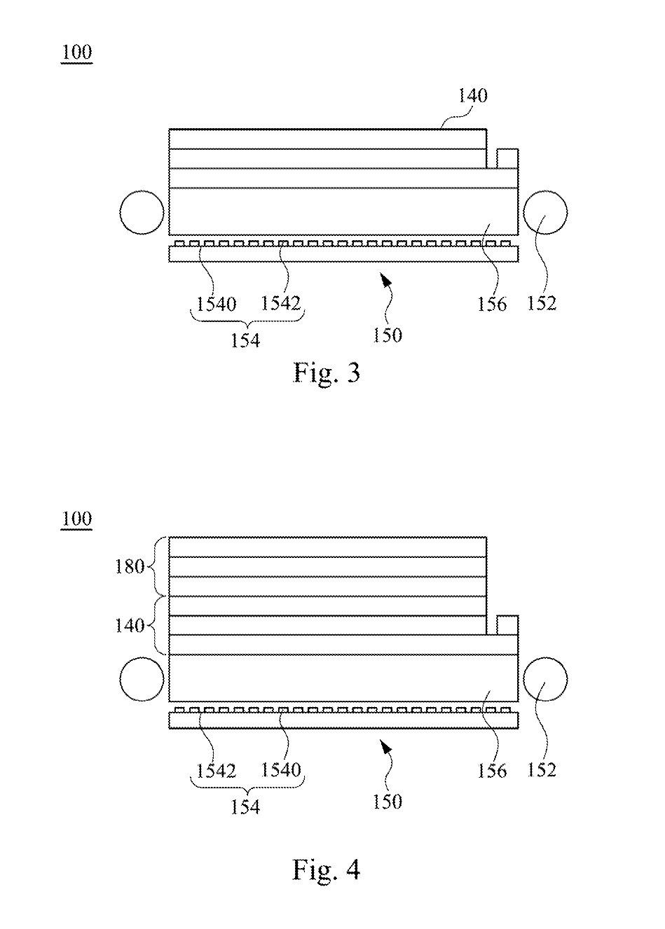

FIG. 3 is a cross-sectional schematic view of a second embodiment of the photovoltaic mobile device 100 of the invention. The photovoltaic mobile device 100 includes the backlight module 150 and the liquid crystal display panel 140. The backlight module 150 includes the photovoltaic substrate 154 having the strip type photovoltaic components 1540 and the reflection strips 1542 the light guide plate 156 disposed on photovoltaic substrate 154, and the light sources 152. The liquid crystal display panel 140 is disposed on the light guide plate 156. About 5% of solar light emitting on the liquid crystal display panel 140 passes through the liquid crystal display panel 140 and is utilized by the strip type photovoltaic components 1540. In this embodiment, the liquid crystal display panel 140 can be a normally white type liquid crystal display panel, thereby allowing more solar light to enter into the photovoltaic mobile device 100 and be utilized by the strip type photovoltaic components 1540. FIG. 4 is a cross-sectional schematic view of a third embodiment of the photovoltaic mobile device of the invention. The photovoltaic mobile device 100 may further include a touch panel 180. The touch panel 180 is disposed on the liquid crystal display panel 140. The touch panel 180 can utilize in-cell or on-cell touch technology, or out-cell or one glass solution touch technology. The touch panel 180 and the liquid crystal display panel 140 can be separate elements. Alternatively, the touch panel 180 can be integrated with the liquid crystal display panel 140. For example, a bottom substrate of the touch panel 180 can be integrated with a top substrate of the liquid crystal display panel 140 in the same substrate (on-cell).

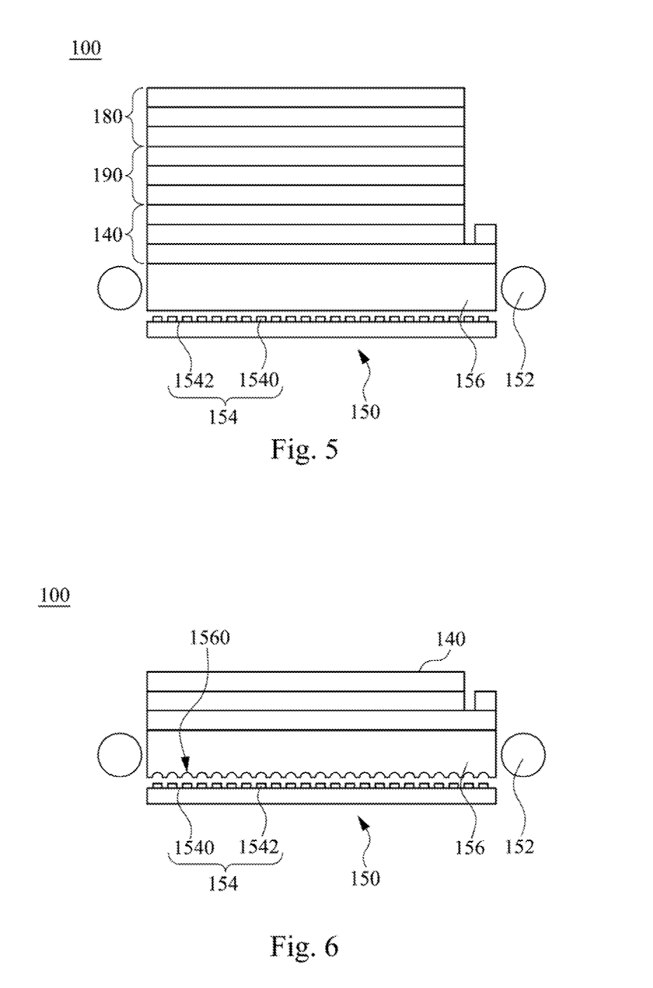

FIG. 5 is a cross-sectional schematic view of a fourth embodiment of the photovoltaic mobile device 100 of the invention. In addition to the touch panel 180, the photovoltaic mobile device 100 may further include a 3D-barrier 190. The 3D-barrier 190 is disposed above the backlight module 150. In this embodiment, the 3D-barrier 190 is disposed between the liquid crystal panel 140 and the touch panel 180.

The 3D-barrier 190 may include a plurality of optical gratings. The 3D-barrier 190 is utilized to change the optical path of the light emitted from the liquid crystal display panel 140, thereby providing a 3D image for viewing by a user.

The 3D barrier 190, the liquid crystal display panel 140, and the touch panel 180 can be three separate elements. Alternatively, the 3D-barrier 190 can be integrated with the liquid crystal display panel 140. For example, a bottom substrate of the 3D-barrier 190 can be integrated with a top substrate of the liquid crystal display panel 140 in the same substrate. In other embodiments, the 3D barrier 190 can be integrated with the touch panel 180. For example, a top substrate of the 3D-barrier 190 can be integrated with a bottom substrate of the touch panel 180 in the same substrate.

FIG. 6 is a cross-sectional schematic view of a fifth embodiment of the photovoltaic mobile device 100 of the invention. The light guide plate 156 of the photovoltaic mobile device 100 includes a plurality of strip cavities 1560. The strip cavities 1560 are disposed at the surface of the light guide plate 156 facing the photovoltaic substrate 154. The strip cavities 1560 are disposed corresponding to the strip type photovoltaic components 1540 respectively. The cross-sectional profile of the strip cavities 1560 is a curved shape in order to guide light onto the strip type photovoltaic components 1540. The width of the strip type photovoltaic components 1540 is extremely small, so that the display function of the photovoltaic device 100 is not affected by the strip type photovoltaic components 1540. By guiding light toward the strip type photovoltaic components 1540, the strip cavities 1560 increase the electricity generation capability of the strip type photovoltaic components 1540.

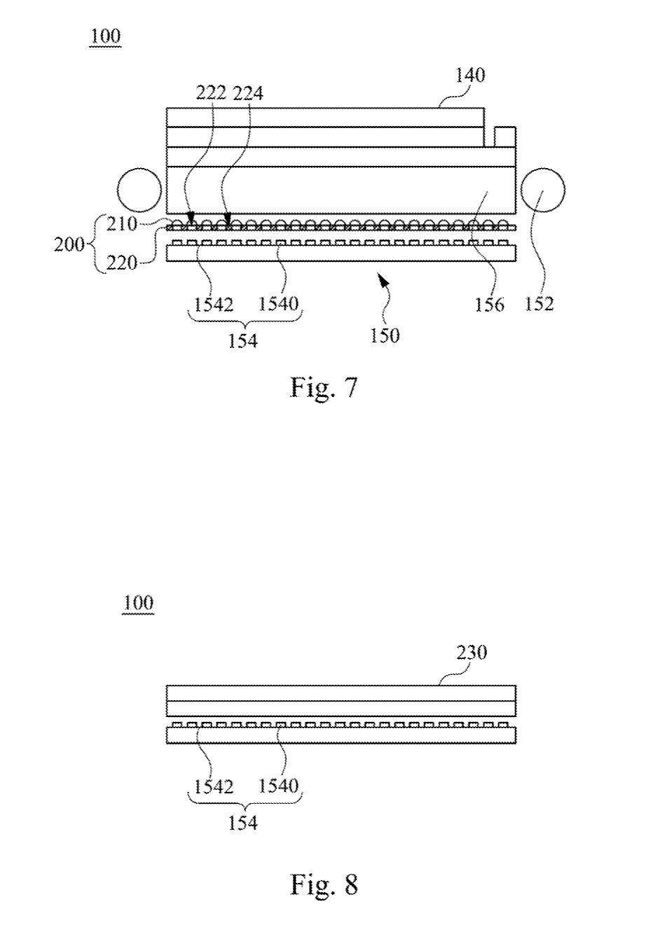

FIG. 7 is a cross-sectional schematic view of a sixth embodiment of the photovoltaic mobile device 100 of the invention. In order to better hide the strip type photovoltaic components 1540 on the photovoltaic substrate 154, the photovoltaic mobile device 100 may further include an optical component 200. The optical component 200 includes a micro lens array surface 210 facing the liquid crystal display panel 140. The optical component 200 also includes an alternative light passage surface 220 facing the photovoltaic substrate 154. The micro lens array surface 210 includes a plurality of micro lenses which guide and focus the light. The alternative light passage surface 220 includes a plurality of first one-way light passages 222, and a plurality of second one-way light passages 224. The first one-way light passages 222 and the second one-way passages 224 are alternatingly arranged. The first one-way light passages 222 are arranged corresponding to the strip type photovoltaic components 1540 respectively, so that the light guided by the micro lens array surface 222 may pass through the first one-way light passages 222 and be received by the strip type photovoltaic components 1540. The second one-way light passages 224 are disposed corresponding to the reflection strips 1542 so that the light reflected by the reflection strips 1542 may pass through the second one-way light passages 224 and enter the liquid crystal display panel 140 for being utilized as a part of the backlight for the liquid crystal display panel 140. The light reflected by the reflection strips 1542 includes the light passing through the first one-way light passages 222 but not entering the strip type photovoltaic components 1540, and side leakage light provided by the light sources 152.

By including the optical component 200 in the photovoltaic mobile device 100, the light guided by the micro lens array surface 210 may pass through the first one-way light passages 222 and be received by the strip type photovoltaic components 1540, and the light reflected by the reflection strips 1542 may pass through the second one-way light passages 224 and enter the liquid crystal display panel 140. The entrance path and the exit path of the light are different and separated, so that the strip type photovoltaic components 1540 can be hidden and mura of liquid crystal display panel 140 can be prevented.

FIG. 8 is a cross-sectional schematic view of a seventh embodiment of the photovoltaic mobile device 100 of the invention. The photovoltaic mobile device 100 includes the photovoltaic substrate 154 having the strip type photovoltaic components 1540 and the reflection strips 1542, and an organic light emitting diode (OLED) display panel 230 disposed on the photovoltaic substrate 154.

A part of the leakage light provided by the OLED display panel 230 is received by the strip type photovoltaic components 1540 and converted into electric energy for utilization by the photovoltaic mobile device 100. Another part of the leakage light is reflected back toward the OLED display panel 230 by the reflection strips 1542, thereby raising the brightness of the OLED display panel 230.

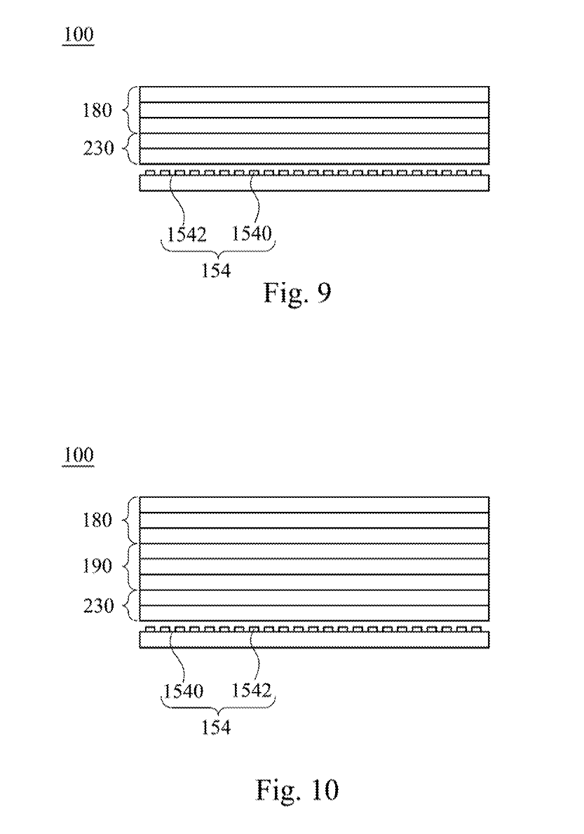

FIG. 9 is a cross-sectional schematic view of an eighth embodiment of the photovoltaic mobile device 100 of the invention. The photovoltaic mobile device 100 may further include the touch panel 180. The touch panel 180 is disposed on the OLED display panel 230. The touch panel 180 can utilize in-cell or out-cell touch technology. The touch panel 180 and the OLED display panel 230 can be separate elements. Alternatively, the touch panel 180 can be integrated with the OLED display panel 230. For example, a bottom substrate of the touch panel 180 can be integrated with a top substrate of the OLED display panel 230 in the same substrate.

FIG. 10 is a cross-sectional schematic view of a ninth embodiment of the photovoltaic mobile device 100 of the invention. In addition to the touch panel 180, the photovoltaic mobile device 100 may further include a 3D-barrier 190. The 3D-barrier 190 is disposed on the OLED display panel 230. In this embodiment, the 3D-barrier 190 is disposed between the OLED display panel 230 and the touch panel 180.

The 3D-barrier 190 includes a plurality of optical gratings. The 3D-barrier 190 is utilized to change the optical path of the light emitted from the OLED display panel 230, thereby providing a 3D image for viewing by a user.

The 3D barrier 190, the OLED display panel 230, and the touch panel 180 can be three separate elements. Alternatively, the 3D-barrier 190 can be integrated with the OLED display panel 230. For example, a bottom substrate of the 3D-barrier 190 can be integrated with a top substrate of the OLED display panel 230 in the same substrate. In other embodiments, the 3D barrier 190 can be integrated with the touch panel 180. For example, a top substrate of the 3D-barrier 190 can be integrated with a bottom substrate of the touch panel 180 in the same substrate.

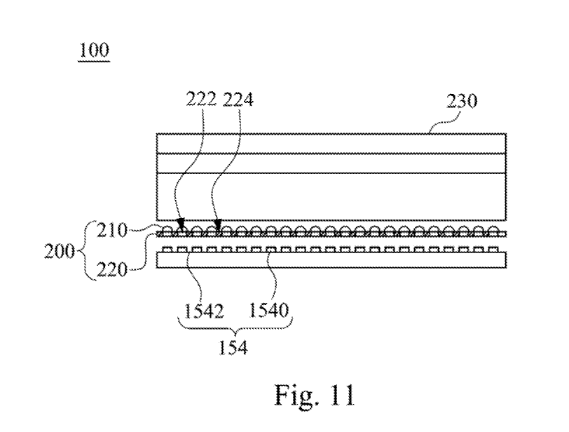

FIG. 11 is a cross-sectional schematic view of a tenth embodiment of the photovoltaic mobile device 100 of the invention. The photovoltaic mobile device 100 may further include the optical component 200. The optical component 200 includes the micro lens array surface 210 facing OLED display panel 230. The optical component 200 also includes the alternative light passage surface 220 facing the photovoltaic substrate 154. The micro lens array surface 210 includes the plurality of micro lenses which guide and focus the light. The alternative light passage surface 220 includes the plurality of first one-way light passages 222, and the plurality of second one-way light passages 224. The first one-way light passages 222 and the second one-way passages 224 are alternatingly arranged. The first one-way light passages 222 are arranged corresponding to the strip type photovoltaic components 1540 respectively, so that the light guided by the micro lens array surface 222 may pass through the first one-way light passages 222 and be received by the strip type photovoltaic components 1540. The second one-way light passages 224 are disposed corresponding to the reflection strips 1542, so that the light reflected by the reflection strips 1542 may pass through the second one-way light passages 224 and enter OLED display panel 230. The light reflected by the reflection strips 1542 includes the light passing through the first one-way light passages 222 but not entering the strip type photovoltaic components 1540.

By including the optical component 200 in the photovoltaic mobile device 100, the light guided by the micro lens array surface 210 may pass through the first one-way light passages 222 and be received by the strip type photovoltaic components 1540, and the light reflected by the reflection strips 1542 may pass through the second one-way light passages 224 and enter t OLED display panel 230. The entrance path and the exit path of the light are different and separated, so that the strip type photovoltaic components 1540 can be hidden and mura of OLEO display panel 230 can be prevented.

The photovoltaic mobile device uses the strip type photovoltaic components which are disposed behind the display surface to collect and convert light provided by a backlight module into electric energy which can be utilized by the mobile device, As a result, the standby time of the mobile device can be increased and the charge frequency can be reduced.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A photovoltaic mobile device comprising:
a backlight module comprising a plurality of light sources, a photovoltaic substrate, and a light guide plate, wherein the light sources are disposed at a side of the light guide plate, and the light guide plate is disposed above the photovoltaic substrate; and
a liquid crystal display panel disposed on the light guide plate, wherein the photovoltaic substrate comprises a plurality of strip type photovoltaic components.

2. The photovoltaic mobile device of claim 1, further comprising:
a light source bracket, wherein the light sources are disposed in the light source bracket; and
a photovoltaic layer coated on a surface of the light source bracket facing the light sources.

3. The photovoltaic mobile device of claim 1, wherein the liquid crystal display panel is a normally white liquid crystal display panel.

4. The photovoltaic mobile device of claim 1, further comprising a touch panel disposed on the liquid crystal display panel.

5. The photovoltaic mobile device of claim 1 further comprising a 3D-barrier disposed on the liquid crystal display panel.

6. The photovoltaic mobile device of claim 1, wherein the light guide plate comprises a plurality of strip cavities disposed on a surface of the light guide plate facing the photovoltaic substrate, the strip cavities are disposed corresponding to the strip type photovoltaic components respectively, and a cross-sectional profile of the strip cavities is a curved shape.

7. The photovoltaic mobile device of claim 1, further comprising an optical component, the optical component comprising a micro lens array surface facing the liquid crystal display panel, and an alternative light passage surface facing the photovoltaic substrate.

8. The photovoltaic mobile device of claim 7, wherein the alternative light passage surface comprises a plurality of first one-way light passages and a plurality of second one-way light passages, and the first one-way light passages and the second one-way light passages are alternatingly arranged.

9. The photovoltaic mobile device of claim 1, wherein the photovoltaic substrate further comprises a plurality of reflection strips, and the strip type photovoltaic components and the reflection strips are alternatingly arranged.

10. A photovoltaic mobile device comprising:
a photovoltaic substrate comprising a plurality of strip type photovoltaic components; and
an organic light emitting diode display panel disposed on the photovoltaic substrate.

11. The photovoltaic mobile device of claim 10, further comprising a touch panel disposed on the organic light emitting diode display panel.

12. The photovoltaic mobile device of claim 10, further comprising a 3D-barrier disposed on the organic light emitting diode display panel.

13. The photovoltaic mobile device of claim 10, further comprising an optical component, the optical component comprising a micro lens array surface facing the organic light emitting diode display panel, and an alternative light passage surface facing the photovoltaic substrate.

14. The photovoltaic mobile device of claim 13, wherein the alternative light passage surface comprises a plurality of first one-way light passages and a plurality of second one-way light passages, and the first one-way light passage and the second one-way light passage are alternatingly arranged.

15. The photovoltaic mobile device of claim 10, wherein the photovoltaic substrate further comprises a plurality of reflection strips, and the strip type photovoltaic components and the reflection strips are alternatingly arranged.
